(19) United States
(12) Patent Application Publication
(10) Pub. No.: US 2020/0251499 A1
(43) Pub. Date: Aug. 6, 2020

(54) Display Panel and Method for Manufacturing Thereof

(71) Applicants: BOE Technology Group Co., Ltd., Beijing (CN); Hefei Xinsheng Optoelectronics Technology Co., Ltd., Hefei (CN)

(72) Inventors: Peng Wu, Beijing (CN); Xuebing Jiang, Beijing (CN); Jilei Gao, Beijing (CN)

(73) Assignees: BOE Technology Group Co., Ltd., Beijing (CN); Hefei Xinsheng Optoelectronics Technology Co., Ltd., Hefei City (CN)

(21) Appl. No.: 15/767,302

(22) PCT Filed: Sep. 27, 2017
(86) PCT No.: PCT/CN2017/103723

§ 371 Date: Apr. 10, 2018

(30) Foreign Application Priority Data
Oct. 24, 2016 (CN) 201610937784.X

(51) Int. Cl. H01L 27/12

(52) U.S. Cl. CPC H01L 27/124; H01L 27/1259

(57) ABSTRACT

A display panel and a method for manufacturing the same are disclosed. The display panel includes a first substrate and a second substrate which are cell-assembled; a metal layer, a black matrix and a spacer layer are disposed between the first substrate and the second substrate, and the spacer layer includes a plurality of spacers. Orthographic projections of any two of the spacer, the black matrix and the metal layer on the first substrate are at least partially overlapped with each other; the sum of the thicknesses of the spacer, the metal layer and the black matrix in a direction perpendicular to the first substrate is same at any position corresponding to the spacers.

### CROSS-REFERENCE OF RELATED APPLICATION

The present application claims the priority of Chinese patent application No. 201610937784.X filed on Oct. 24, 2016, the disclosure of which is hereby incorporated by reference herein in its entirety.

### TECHNICAL FIELD

Embodiments of the present disclosure relate to a display panel and a method for manufacturing the same.

### BACKGROUND

Liquid crystal displays (LCDs) have many advantages of low radiation, small size, low power consumption, etc., and it is widely used in electronic products such as tablet computer, television or mobile phone.

A liquid crystal display panel comprises an array substrate, a counter substrate and a liquid crystal layer therebetween. The array substrate comprises a metal layer, which is typically deposited by magnetron sputtering, that is, plasma is formed by radio frequency or DC voltage, charged ions with high energy in the plasma collide with the surface of metal target, and the particles of the metal target are escaped from the surface of the metal target, therefore, a metal layer is deposited on the surface of the substrate.

### SUMMARY

Embodiments of the present disclosure provide a display panel and a method for manufacturing the same, in order to make the thickness of the liquid crystal panel be uniform.

At least one of the embodiments of the present disclosure provides a display panel, comprising: a first substrate and a second substrate which are cell-assembled; wherein, a metal layer, a black matrix and a spacer layer are disposed between the first substrate and the second substrate, and the spacer layer comprises a plurality of spacers; orthographic projections of any two of the spacer, the black matrix and the metal layer on the first substrate are at least partially overlapped with each other; and a sum of thicknesses of the spacer, the metal layer and the black matrix in a direction perpendicular to the first substrate is same at any position corresponding to the spacer.

In the display panel according to the embodiments of the present disclosure, the thicknesses of the plurality of spacers are same as one another; the sum of the thicknesses of the metal layer and the black matrix is same at any position corresponding to the spacer.

In the display panel according to the embodiments of the present disclosure, the display panel comprises a plurality of first regions and a plurality of second regions; the thickness of the metal layer in the first region is different from the thickness of the metal layer in the second region; wherein the first regions and the second regions are alternately arranged; the thickness of the black matrix in the first region is different from the thickness of the black matrix in the second region.

In the display panel according to the embodiments of the present disclosure, the metal layer is disposed on the first substrate; the black matrix and the spacer are disposed on the second substrate.

In the display panel according to the embodiments of the present disclosure, the metal layer comprises a gate metal layer, and the gate metal layer comprises a gate line; orthographic projections of the spacer and the gate line on the first substrate are at least partially overlapped with each other.

In the display panel according to the embodiments of the present disclosure, the metal layer comprises a gate metal layer and a source-drain metal layer, the gate metal layer comprises a gate and a gate line, and the source-drain metal layer comprises a source, a drain and a data line; the display panel further comprises a gate insulation layer and an active layer, and the gate, the gate insulation layer, the active layer, the source and the drain forms a TFT; the orthographic projections of the spacer and the TFT on the first substrate are at least partially overlapped with each other.

In the display panel according to the embodiments of the present disclosure, the metal layer comprises a gate metal layer and a source-drain metal layer, the gate metal layer comprises a gate line, and the source-drain metal layer comprises an auxiliary pattern; the auxiliary pattern corresponds to the gate line; the orthographic projections of the spacer and the auxiliary pattern on the first substrate are at least partially overlapped with each other.

In the display panel according to the embodiments of the present disclosure, an area of the orthographic projection of the auxiliary pattern is smaller than an area of the orthographic projection of the spacer on the first substrate, the spacer is against on the auxiliary pattern.

At least one of the embodiments of the present disclosure provides a method for manufacturing a display panel, wherein the display panel comprises a first substrate and a second substrate which are cell-assembled; a metal layer, a black matrix and a spacer layer are formed between the first substrate and the second substrate, and the spacer layer comprises a plurality of spacers; the metal layer is formed by a magnetron sputtering process and a patterning process; orthographic projections of any two of the spacer, the black matrix and the metal layer on the first substrate are at least partially overlapped with each other; a sum of thicknesses of the spacer, the metal layer and the black matrix in a direction perpendicular to the first substrate is same at any position corresponding to the spacer.

In the method for manufacturing a display panel according to the embodiments of the present disclosure, wherein the thicknesses of the plurality of spacers are same as one another; forming the black matrix with a controlled thickness at a position corresponding to the spacer, such that the sum of the thicknesses of the metal layer and the black matrix is same at any position corresponding to the spacer.

In the method for manufacturing a display panel according to the embodiments of the present disclosure, the display panel comprises a plurality of first regions and a plurality of second regions; the thickness of the metal layer in the first region is different from the thickness of the metal layer in the second region; wherein the first regions and the second regions are alternately arranged; the formation of the black matrix comprises: forming a black matrix film by a coating process; wherein a deposition amount of the black matrix material is controlled by adjusting an operating voltage of a coating apparatus, so that the thickness of the black matrix film corresponding to the first region is different from the thickness of the black matrix film corresponding to the second region; exposing the black matrix film by using a mask, and developing to form the black matrix.

In the method for manufacturing a display panel according to the embodiments of the present disclosure, the metal layer is formed on the first substrate; the black matrix and the spacer are formed on the second substrate.

In the method for manufacturing a display panel according to the embodiments of the present disclosure, the metal layer comprises a gate metal layer, the gate metal layer comprises a gate line; orthographic projections of the spacer and the gate line on the first substrate are at least partially overlapped with each other.

In the method for manufacturing a display panel according to the embodiments of the present disclosure, the metal layer comprises a gate metal layer and a source-drain metal layer, the gate metal layer comprises a gate and the gate line, and the source-drain metal layer comprises a source, a drain and a data line; a gate insulation layer and an active layer are further formed in the display panel, and the gate, the gate insulation layer, the active layer, the source and the drain form a TFT; the orthographic projections of the spacer and the TFT on the first substrate are at least partially overlapped with each other.

In the method for manufacturing a display panel according to the embodiments of the present disclosure, the metal layer comprises a gate metal layer and a source-drain metal layer, the gate metal layer comprises a gate line, and the source-drain metal layer comprises an auxiliary pattern; the auxiliary pattern corresponds to the gate line; the orthographic projections of the spacer and the auxiliary pattern on the first substrate are at least partially overlapped with each other.

In the method for manufacturing a display panel according to the embodiments of the present disclosure, an area of the orthographic projection of the auxiliary pattern is smaller than an area of the orthographic projection of the spacer on the first substrate, the spacer is against on the auxiliary pattern.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 schematically illustrates that a metal film is deposited by using a metal target;

FIG. 2 schematically illustrates a liquid crystal display panel;

FIG. 3 schematically illustrates a display panel according to an embodiment of the present disclosure;

FIG. 4A schematically illustrates a top view of a black matrix film according to an embodiment of the present disclosure;

FIG. 4B schematically illustrates a cross-sectional view along a line AA′ of FIG. 4A;

FIG. 5 schematically illustrates a black matrix, a color filter layer and a spacer disposed on a second substrate according to an embodiment of the present disclosure;

FIG. 6A schematically illustrates a display panel in which the spacer corresponds to a gate line according to an embodiment of the present disclosure;

FIG. 6B schematically illustrates a top view of a first substrate according to an embodiment of the present disclosure;

FIG. 7 schematically illustrates a display panel in which the spacer corresponds to a TFT, according to an embodiment of the present disclosure;

FIG. 8A schematically illustrates a display panel in which the spacer corresponds to an auxiliary pattern according to an embodiment of the present disclosure;

FIG. 8B schematically illustrates a top view of another first substrate according to an embodiment of the present disclosure;

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

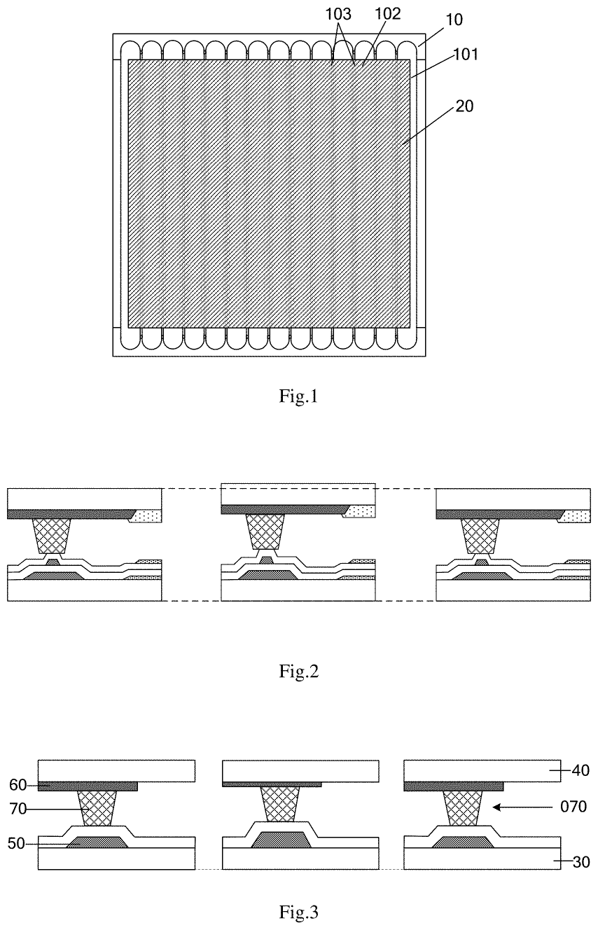

For example, as illustrated in FIG. 1, a metal target used for magnetron sputtering is generally formed by splicing a plurality of stripe-shaped metal targets 101, and the metal target is centrosymmetric with a glass substrate 20 (after rotating the glass substrate 20 by 180°, the corresponding position between the glass substrate 20 and the metal substrate 10 is completely overlapped with that of pre-rotation).

In the process of magnetron sputtering, the particles are escaped from the surface of the metal target, and there is inevitably a difference in particle distribution between the metal target central region 102 and the metal target splicing region 103, because the metal target central region 102 and the metal target splicing region 103 have different thickness, as a result, the thickness of the metal layer deposited on the glass substrate 20 is periodically varied, and the cell thickness of the liquid crystal display panel after cell-assembly is also periodically varied, i.e., the cell thickness is not uniform (as illustrated in FIG. 2). For example, at the location where the cell thickness is thicker, the color temperature is small, and warm color is displayed; at the location where the cell thickness is thinner, the color temperature is large, and cool color is displayed. When the display panel is displayed, a periodic color distribution is appeared, and the picture quality of liquid crystal panel is severely affected.

An embodiment of the present disclosure provides a display panel, as illustrated in FIG. 3, which comprises a first substrate 30 and a second substrate 40 which are cell-assembled; a metal layer 50, a black matrix 60 and a spacer layer 070 are disposed between the first substrate 30 and the second substrate 40, and the spacer layer 070 comprises a plurality of spacers 70. Orthographic projections of any two of the metal layer 50, the black matrix 60 and the spacer 70 on the first substrate 30 are at least partially overlapped with each other; a sum of thicknesses of the spacer 70, the metal layer 50 and the black matrix 60 in a direction perpendicular to the first substrate 30 is same at any position corresponding to the spacers 70.

The following points are needed to explain.

Firstly, the metal layer 50, the black matrix 60 and the spacer 70 are not limited to be disposed on the first substrate 30 or the second substrate 40, for example, the metal layer 50, the black matrix 60 and the spacer 70 may be all disposed on the first substrate 30 or the second substrate 40, and also may be separately disposed on the first substrate 30 or the second substrate 40.

For example, the material of the black matrix 60 may be an opaque organic material (such as a resin), or an opaque inorganic material, as long as it has a light-shielding effect.

For example, the material of the spacer 70 may be a photosensitive resin material or a non-photosensitive resin material. In the case that the material of the spacer 70 is the photosensitive resin material, the spacer 70 may be formed directly by means of film forming, exposing and developing processes. In the case that the material of the spacer 70 is the non-photosensitive resin material, the spacer 70 may be formed by means of film forming, photoresist forming, exposing, developing and etching processes. The spacer 70 is configured to support the first substrate 30 and the second substrate 40, so that cell thickness of the display panel can be obtained.

The shape of the metal layer 50 is not limited in the disclosure, as long as its orthographic projection is overlapped with orthographic projections of the black matrix 60 and the spacer 70 on the first substrate 30.

Secondly, the orthographic projections of any two of the spacer 70, the black matrix 60 and the metal layer 50 on the first substrate 30 are at least partially overlapped with each other. That is, the orthographic projection of the spacer 70 is at least partially overlapped with the orthographic projection of the black matrix 60 on the first substrate 30, the orthographic projection of the spacer 70 is at least partially overlapped with the orthographic projection of the metal layer 50 on the first substrate 30, and the orthographic projection of the black matrix 60 is at least partially overlapped with the orthographic projection of the metal layer 50 on the first substrate 30. They are at least partially overlapped, i.e., there is an overlapped area.

Thirdly, as described above, due to the limitation of magnetron sputtering process used in preparation of the metal layer 50, the metal layer 50 has different thickness at different positions. In order to make the sum of the thicknesses of the spacer 70, the metal layer 50 and the black matrix 60 equal at any position corresponding to the spacers 70, the thickness of the black matrix 60 can be adjusted, or the thickness of the spacer 70 can be adjusted, or both the thickness of the black matrix 60 and the thickness of the spacer 70 can be adjusted.

For example, as illustrated in FIG. 3, the sum of the thicknesses of the spacer 70, the metal layer 50 and the black matrix 60 is same at any position corresponding to the spacer 70, by only adjusting the thickness of the black matrix 60 at different positions.

Embodiments of the present disclosure provide a display panel. The black matrix 60, the spacer 70 and the metal layer 50 are disposed between the first substrate 30 and the second substrate 40, and the sum of the thicknesses of the black matrix 60, the spacer 70 and the metal layer 50 is same at any position corresponding to the spacer 70, therefore, the cell thickness of the display panel is uniform, and then the picture quality of the display panel can be improved.

For example, as illustrated in FIG. 3, the spacers 70 have a same thickness at any position; the sum of the thicknesses of the metal layer 50 and the black matrix 60 could be the same at different positions corresponding to the spacers 70 by adjusting the thickness of the black matrix 60.

In the display panel provided in an embodiment of the present disclosure, the thickness of the spacer 70 at each position keeps uniform, and the thickness of the black matrix 60 is varied in control, in order to make the sum of the thicknesses of the metal layer 50 and the black matrix 60 same at any position corresponding to the spacer 70. For example, in comparison with controlling both the thicknesses of the spacer 70 and the black matrix 60, the process can be simplified by controlling the thickness of the black matrix 60 only, in order to make the sum of the thicknesses of the spacer 70, the metal layer 50 and the black matrix 60 equal at any position corresponding to the spacer 70.

It is considered that while the metal layer 50 is prepared, the thickness of the metal layer 50 is periodically varied according to the central region and the splicing region of the metal target, that is, the thickness of the metal layer 50 corresponding to a first region is different from the thickness of the metal layer 50 corresponding to a second region of the display panel. For example, the first region and the second region are alternately arranged. Herein the first region and the second region respectively correspond to the splicing region and the central region of the metal target.

For example, the thickness of the black matrix 60 is also periodically varied according to the central region and the splicing region of the metal target, that is, the thickness of the black matrix 60 corresponding to the first region is different from the thickness of the black matrix 60 corresponding to the second region, therefore, the sum of the thicknesses of the black matrix 60 and the metal layer 50 corresponding to the first region is equal to the sum of the thicknesses of the black matrix 60 and the metal layer 50 corresponding to the second region.

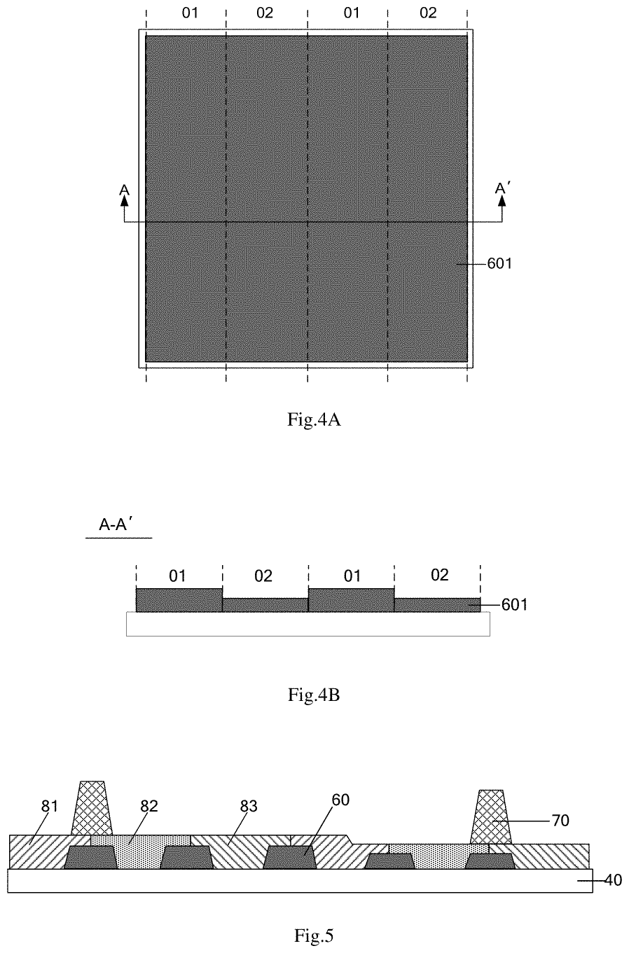

For example, the first region corresponds to the splicing region of the metal target, and the second region corresponds to the central region of the metal target. Since the thickness of the metal layer corresponding to the splicing region is relatively thin, and the thickness of the metal layer corresponding to the central region is relatively thick, as illustrated in FIGS. 4A and 4B, during the formation of the black matrix film 601, the deposition amount of the black matrix material can be controlled by adjusting an operating voltage of a coating apparatus, so that the thickness of the black matrix film 601 corresponding to the first region 01 is different from that corresponding to the second region 02, that is, the thickness of the black matrix film 601 corresponding to the first region 01 is relatively thick, and the thickness of the black matrix film 601 corresponding to the second region 02 is relatively thin. For example, the black matrix film may be exposed by using a mask, and then underwent a development process, so as to form the black matrix 60. That is, the thickness of the black matrix 60 corresponding to the first region 01 is thicker than the thickness of the black matrix 60 corresponding to the second region 02.

According to the embodiments of the present disclosure, the thickness of the black matrix 60 may be varied in different regions, in order to make the thickness of the black matrix 60 respectively corresponding to the first region 01 and the second region 02 different. It is no need to change the design of a mask, and it can optimize the process, therefore, the cost is reduced. During the preparation of the black matrix 60, the deposition amount of the black matrix material may be controlled by adjusting the operating voltage of the coating apparatus.

For example, as illustrated in FIG. 3, the metal layer 50 is disposed on the first substrate 30; the black matrix 60 and the spacer 70 are disposed on the second substrate 40.

For example, the spacer 70 may be disposed on a side of the black matrix 60 away from the second substrate 40.

According to the embodiments of the present disclosure, the metal layer 50, the black matrix 60 and the spacer 70 may be disposed on different substrates respectively, the manufacturing process is mature, and it is no need to change the manufacturing process, therefore, the cost will not be increased.

For another example, as illustrated in FIG. 5, the color filter layer is disposed on the second substrate 40. For example, the color filter layer comprises three primary color filter patterns, i.e., a first primary color filter pattern 81, a second primary color filter pattern 82 and a third primary color filter pattern 83. For example, each of the first primary color filter pattern 81, the second primary color filter pattern 82 and the third primary color filter pattern 83 is disposed in one of sub-pixels.

For example, the black matrix 60 may be formed on the second substrate 40 firstly; thereafter, the first primary color filter pattern 81, the second primary color filter pattern 82 and the third primary color filter pattern 83 are respectively formed. For example, the first primary color filter pattern 81, the second primary color filter pattern 82 and the third primary color filter pattern 83 are respectively formed in three sub-pixels of each pixel, and the filter patterns in adjacent sub-pixels are separated by the black matrix 60. After that, the spacer 70 is formed, and the orthographic projection of the spacer 70 on the second substrate 40 is overlapped with the orthographic projection of the black matrix 60 on the second substrate 40.

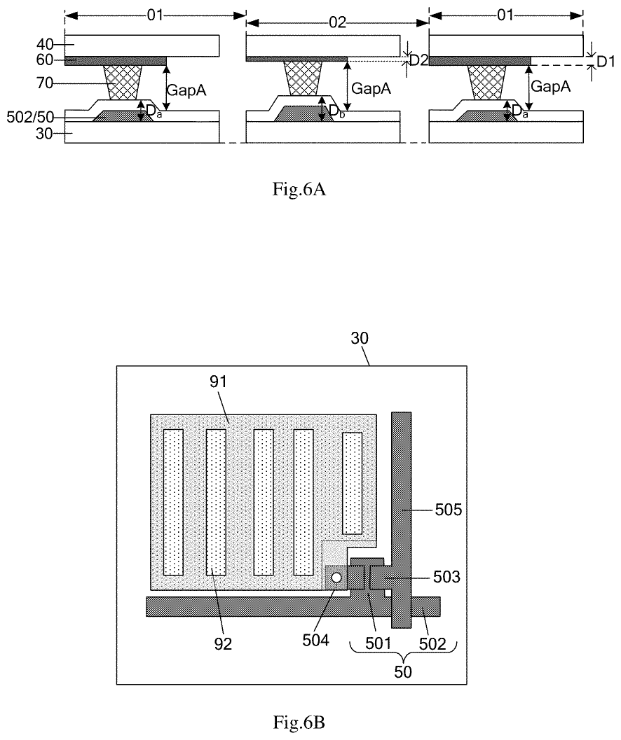

For example, as illustrated in FIGS. 6A and 6B, the metal layer 50 comprises a gate metal layer, the gate metal layer comprises a gate 501 and a gate line 502; the orthographic projections of the spacer 70 and the gate line 502 on the first substrate 30 are at least partially overlapped with each other.

For example, as illustrated in FIG. 6A, the gate metal layer is disposed on the first substrate 30. For example, as illustrated in FIG. 6B, a gate insulation layer, an active layer and a source-drain metal layer may further be disposed on the first substrate 30, and the source-drain metal layer comprises a source 503, a drain 504 and a data line 505. The gate 501, the gate insulation layer, the active layer, the source 503 and the drain 504 form a thin film transistor (TFT).

As an example, the first region 01 corresponds to the splicing region of the metal target, and the second region 02 corresponds to the central region of the metal target. As illustrated in FIG. 6A, a total thickness of the layers on the first substrate 30 corresponding to the spacer 70 in the first region 01 may be referred to as Dₐ, and a total thickness of the layers on the first substrate 30 corresponding to the spacer 70 in the second region 02 may be referred to as D_{b}. Since the thickness of the gate line 502 corresponding to the first region 01 is thinner than the thickness of the gate line 502 corresponding to the second region 02, the thickness of the black matrix 60 corresponding to the first region 01, which is referred to as D1, is thicker than the thickness of the black matrix 60 corresponding to the second region 02, which is referred to as D2, i.e., D1−D2=D_{b}−Dₐ, then the cell thickness GapA of the display panel is same at the first and second regions, and then the uniformity of the cell thickness of the display panel is achieved.

It is noted that, the above-stated thickness may be a thickness in a direction perpendicular to the first substrate or the second substrate.

Further, as illustrated in FIG. 6B, a pixel electrode 91 and a common electrode 92 are further disposed on the first substrate 30. For example, a multi-dimensional electric field may be generated between the pixel electrode 91 and the common electrode 92 in order to drive the rotation of liquid crystals. As another example, the common electrode 92 may also be disposed on the second substrate 40. For example, the pixel electrode 91 may be a slit electrode, the common electrode may be a plate electrode, but it is not limited thereto.

According to the embodiments of the present disclosure, the orthographic projections of the spacer 70 and the gate line 502 on the first substrate 30 are at least partially overlapped with each other, therefore, when the spacer 70 is configured to support the cell thickness, the influence on an active display region can be avoided.

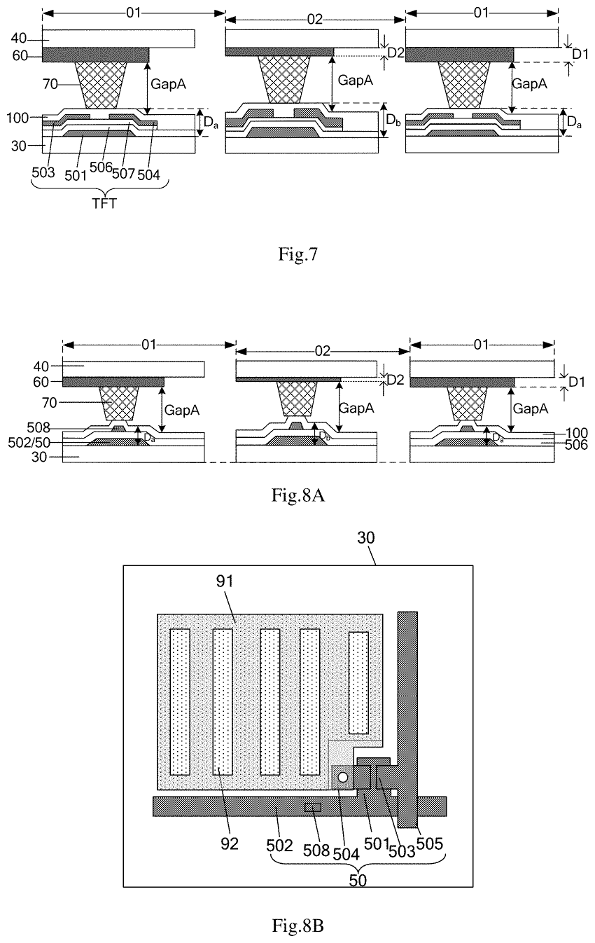

Alternatively, as illustrated in FIGS. 7 and 6B, the metal layer 50 comprises the gate metal layer and the source-drain metal layer, the gate metal layer comprises the gate 501 and the gate line 502, and the source-drain metal layer comprises the source 503, the drain 504 and the data line 505. The gate insulation layer 506 and the active layer are further disposed in the display panel. The gate 501, the gate insulation layer 506, the active layer 507, the source 503 and the drain 504 form a TFT; the orthographic projections of the spacer 70 and the TFT on the first substrate 30 are at least partially overlapped with each other.

For example, as illustrated in Fig.7, the gate metal layer, the source-drain metal layer, the gate insulation layer 506 and the active layer 507 are disposed on the first substrate 30.

As an example, the first region 01 corresponds to the splicing region of the metal target, and the second region 02 corresponds to the central region of the metal target. As illustrated in FIG. 7, the total thickness of the layers corresponding to the spacer 70 in the first region 01 of the first substrate 30 may be referred to as Dₐ, and the total thickness of the layers corresponding to the spacer 70 in the second region 02 of the first substrate 30 may be referred to as D_{b}. Since the total thickness of the gate metal layer and the source-drain metal layer corresponding to the first region 01 is thinner than the total thickness of the gate metal layer and the source-drain metal layer corresponding to the second region 02, the thickness of the black matrix 60 corresponding to the first region 01, which is referred to as D1, is thicker than the thickness of the black matrix 60 corresponding to the second region 02, which is referred to as D2, i.e., D1−D2=D_{b}−Dₐ, then the cell thickness GapA of the display panel is kept uniform, and then the uniformity of the cell thickness of the display panel is achieved.

It is noted that, the type of TFT is not limited in the present disclosure, and it may be a bottom-gate TFT or a top-gate TFT.

According to the embodiments of the present disclosure, the orthographic projections of the spacer 70 and TFT on the first substrate 30 are at least partially overlapped with each other, therefore, when the spacer 70 is configured to support the cell thickness, the influence on an effective display region can be avoided.

Alternatively, as illustrated in FIGS. 8A and 8B, the metal layer 50 comprises the gate metal layer and the source-drain metal layer, the gate metal layer comprises the gate 501 and the gate line 502, and the source-drain metal layer comprises the source 503, the drain 504, the data line 505 and an auxiliary pattern 508; the auxiliary pattern 508 corresponds to the gate line 502; the orthographic projections of the spacer 70 and the auxiliary pattern 508 on the first substrate 30 are at least partially overlapped with each other.

For example, as illustrated in FIGS. 8A and 8B, both the gate metal layer and the source-drain metal layer are disposed on the first substrate 30, in this case, the gate insulation layer and the active layer are further disposed on the first substrate 30, and the gate 501, the gate insulation layer, the active layer, the source 503 and the drain 504 form a TFT.

As an example, the first region 01 corresponds to the splicing region of the metal target, and the second region 02 corresponds to the central region of the metal target. As illustrated in FIG. 8A, the total thickness of the layers corresponding to the spacer 70 in the first region 01 of the first substrate 30 may be referred to as Dₐ, and the total thickness of the layers corresponding to the spacer 70 in the second region 02 of the first substrate 30 may be referred to as D_{b}. Since the total thickness of the gate metal layer and the source-drain metal layer corresponding to the first region 01 are thinner than the total thickness of the gate metal layer and the source-drain metal layer corresponding to the second region 02, the thickness of the black matrix corresponding to the first region 01, which is referred to as D1, is thicker than the thickness of the black matrix corresponding to the second region 02, which is referred to as D2, i.e., D1−D2=D_{b}−Dₐ, then the cell thickness GapA of the display panel is kept uniform, and then the uniformity of the cell thickness of the display panel is achieved.

It is noted that, the auxiliary pattern 508, the source 503 and the drain 504 are formed by a same single patterning process.

Since the material of the spacer is an elastic resin material, and an area of an orthographic projection of the auxiliary pattern 508 on the first substrate 30 is smaller than an area of an orthographic projection of the spacer 70 on the first substrate 30, the spacer 70 may be against on the auxiliary pattern 508, therefore, the relative movement between the spacer 70 and the first substrate 30 is reduced, and then the influence on the liquid crystal display panel due to unstable support and static electricity caused by friction can be avoided.

An embodiment of the present disclosure provides a method for manufacturing a display panel, as illustrated in FIG. 3, the display panel comprises a first substrate 30 and a second substrate 40 which are cell-assembled together; a metal layer 50, a black matrix 60 and a spacer layer 070 are disposed between the first substrate 30 and the second substrate 40, and the spacer layer 070 comprises a plurality of spacers 70. For example, the metal layer 50 is formed by a magnetron sputtering process and a patterning process. Orthographic projections of any two of the spacers 70, the black matrix 60 and the metal layer 50 on the first substrate 30 are at least partially overlapped with each other; a sum of thicknesses of the spacer 70, the metal layer 50 and the black matrix 60 in a direction perpendicular to the first substrate 30 is same at any position corresponding to the spacers 70.

Embodiments of the present disclosure provide a method for manufacturing the display panel. The black matrix 60, the spacer 70 and the metal layer 50 are disposed between the first substrate 30 and the second substrate 40, and the sum of the thicknesses of the black matrix 60, the spacer 70 and the metal layer 50 is same at any position corresponding to the spacers 70, therefore, the cell thickness of the display panel is uniform, and then the picture quality of the display panel can be increased.

For example, as illustrated in FIG. 3, the thicknesses of the spacers 70 are same as each other; at any position corresponding to the spacer 70, the sum of the thicknesses of the metal layer 50 and the black matrix 60 could be same by adjusting the thickness of the black matrix 60.

For example, in order to make the sum of the thicknesses of the metal layer 50 and the black matrix 60 equal at any position corresponding to the spacer 70, the thickness of the spacer 70 is not changed while the thickness of the black matrix 60 is varied. For example, since the thickness of the spacer 70 is not changed, in comparison with controlling both the thickness of the spacer 70 and the black matrix 60, the process can be simplified by varying only the thickness of the black matrix 60, such that the sum of the thicknesses of the spacer 70, the metal layer 50 and the black matrix 60 is same at any position corresponding to the spacer 70.

For another example, the thickness of the metal layer 50 corresponding to a first region is different from that corresponding to a second region of the display panel; for example, the first region and the second region are alternately arranged.

In this case, the black matrix 60 is formed as illustrated in FIGS. 4A and 4B, the formation of the black matrix 60 comprises: forming a black matrix film 601 by a coating process. For example, a deposition amount of the black matrix material can be controlled by adjusting an operating voltage of a coating apparatus, so that the thickness of the black matrix film 601 corresponding to the first region 01 is different from that corresponding to the second region 02; the black matrix film 601 is exposed by using a mask, and then underwent a development process, thus the black matrix 60 is formed.

For example, the first region 01 corresponds to the splicing region of the metal target, and the second region 02 corresponds to the central region of the metal target.

For example, while the first region 01 corresponds to the splicing region of the metal target, a deposition amount of the black matrix material is increased by increasing the operating voltage of the coating apparatus, so that the thickness of the black matrix film 601 corresponding to the first region 01 becomes thicker. While the second region 02 corresponds to the central region of the metal target, the deposition amount of the black matrix is reduced by reducing the operating voltage of the coating apparatus, so that the thickness of the black matrix film 601 corresponding to the second region 02 becomes thinner. During the preparation of the black matrix film by a coating process, the deposition amount of the black matrix material may be controlled by adjusting the operating voltage of the coating apparatus, so that the thickness of the black matrix film 601 corresponding to the first region 01 is different from that corresponding to the second region 02; during the process, the black matrix 60 having different thicknesses in different regions is formed, and it is no need to varying the design of a mask, therefore, the cost is reduced.

For example, forming the black matrix 60 comprises: forming the black matrix film with a uniform thickness, exposing the black matrix film by using a grayscale mask and developing, to form the black matrix 60 having different thicknesses in different regions. In addition, the black matrix may also be formed by an inkjet printing process.

For example, as illustrated in FIGS. 3 and 5, the metal layer 50 is formed on the first substrate 30; the black matrix 60 and the spacer 70 are formed on the second substrate 40.

For example, the spacer 70 may be disposed on a side of the black matrix 60 away from the second substrate 40.

According to an embodiment of the present disclosure, the metal layer 50, the black matrix 60 and the spacer 70 may be disposed on different substrate respectively; the manufacturing process is mature, and it is no need to change the manufacturing process, therefore, the cost will not be increased.

For example, as illustrated in FIG. 5, a color filter layer is disposed on the second substrate 40. The color filter layer comprises three primary color filter patterns, i.e., a first primary color filter pattern 81, a second primary color filter pattern 82 and a third primary color filter pattern 83.

For example, the black matrix 60 may be formed on the second substrate 40 firstly; and then the first primary color filter pattern 81, the second primary color filter pattern 82 and the third primary color filter pattern 83 are respectively formed. For example, the first primary color filter pattern 81, the second primary color filter pattern 82 and the third primary color filter pattern 83 are respectively formed in three sub-pixels of each pixel, and the filter patterns in adjacent sub-pixels are separated by the black matrix 60. After that, the spacer 70 is formed. For example, orthographic projections of the spacer 70 and the black matrix 60 on the second substrate 40 are overlapped with each other.

For example, as illustrated in FIGS. 6A and 6B, the metal layer 50 comprises a gate metal layer; the gate metal layer comprises a gate 501 and a gate line 502. For example, the orthographic projections of the spacer 70 and the gate line 502 on the first substrate 30 are at least partially overlapped with each other. Therefore, when the spacer 70 is configured to support the cell thickness, the influence on an active display region can be avoided.

Alternatively, as illustrated in FIGS. 7 and 6B, the metal layer 50 comprises the gate metal layer and a source-drain metal layer, the gate metal layer comprises the gate 501 and the gate line 502, and the source-drain metal layer comprises a source 503, a drain 504 and a data line 505. A gate insulation layer 506 and an active layer 507 are further disposed in the display panel, and the gate 501, the gate insulation layer 506, the active layer 507, the source 503 and the drain 504 form a TFT. For example, the orthographic projections of the spacer 70 and the TFT on the first substrate 30 are at least partially overlapped with each other. Therefore, when the spacer 70 is configured to support the cell thickness, the influence on an active display region can be avoided.

For example, as illustrated in FIGS. 8A and 8B, the metal layer 50 comprises the gate metal layer and the source-drain metal layer, the gate metal layer comprises the gate 501 and the gate line 502, and the source-drain metal layer comprises the source 503, the drain 504, the data line 505 and an auxiliary pattern 508. For example, the auxiliary pattern 508 corresponds to the gate line 502; the orthographic projections of the spacer 70 and the auxiliary pattern 508 on the first substrate 30 are at least partially overlapped with each other.

For example, the auxiliary pattern 508, the source 503 and the drain 504 are formed by a same single patterning process.

Since the material of the spacer is an elastic resin material, and an area of an orthographic projection of the auxiliary pattern 508 on the first substrate 30 is smaller than an area of an orthographic projection of the spacer 70 on the first substrate 30, the spacer 70 may be against on the auxiliary pattern 508, therefore, the relative movement between the spacer 70 and the first substrate 30 is reduced, and then the influence on the liquid crystal display panel due to unstable support and static electricity caused by friction can be avoided.

In the embodiments of the disclosure, the liquid crystal display panel is used as an example for illustration, but embodiments of the present disclosure are not limited thereto, for example, the disclosure may also be applied to other display panels such as a light emitting diode display panel.

Although detailed description has been given above, it is not intended to limit the scope of protection of the disclosure. Those skilled in the art can make some modifications or improvements on the basis of the embodiments of the disclosure, and the modifications or improvements shall all fall within the scope of protection of the present disclosure. The scopes of the disclosure are defined by the accompanying claims

1. A display panel, comprising: a first substrate and a second substrate which are cell-assembled; wherein,
a metal layer, a black matrix and a spacer layer are disposed between the first substrate and the second substrate, and the spacer layer comprises a plurality of spacers;
orthographic projections of any two of the spacer, the black matrix and the metal layer on the first substrate are at least partially overlapped with each other; and a sum of thicknesses of the spacer, the metal layer and the black matrix in a direction perpendicular to the first substrate is same at any position corresponding to the spacer.

2. The display panel according to claim 1, wherein the thicknesses of the plurality of spacers are same as one another;
the sum of the thicknesses of the metal layer and the black matrix is same at any position corresponding to the spacer.

3. The display panel according to claim 2, wherein the display panel comprises a plurality of first regions and a plurality of second regions; the thickness of the metal layer in the first region is different from the thickness of the metal layer in the second region; wherein the first regions and the second regions are alternately arranged;
the thickness of the black matrix in the first region is different from the thickness of the black matrix in the second region.

4. The display panel according to claim 1, wherein the metal layer is disposed on the first substrate;
the black matrix and the spacer are disposed on the second substrate.

5. The display panel according to claim 1, wherein the metal layer comprises a gate metal layer, and the gate metal layer comprises a gate line;
orthographic projections of the spacer and the gate line on the first substrate are at least partially overlapped with each other.

6. The display panel according to claim 1, wherein the metal layer comprises a gate metal layer and a source-drain metal layer, the gate metal layer comprises a gate and a gate line, and the source-drain metal layer comprises a source, a drain and a data line;
the display panel further comprises a gate insulation layer and an active layer, and the gate, the gate insulation layer, the active layer, the source and the drain forms a TFT;
the orthographic projections of the spacer and the TFT on the first substrate are at least partially overlapped with each other.

7. The display panel according to claim 1, wherein the metal layer comprises a gate metal layer and a source-drain metal layer, the gate metal layer comprises a gate line, and the source-drain metal layer comprises an auxiliary pattern; the auxiliary pattern corresponds to the gate line;
the orthographic projections of the spacer and the auxiliary pattern on the first substrate are at least partially overlapped with each other.

8. The display panel according to claim 7, wherein an area of the orthographic projection of the auxiliary pattern is smaller than an area of the orthographic projection of the spacer on the first substrate, the spacer is against on the auxiliary pattern.

9. A method for manufacturing a display panel, wherein the display panel comprises a first substrate and a second substrate which are cell-assembled; a metal layer, a black matrix and a spacer layer are formed between the first substrate and the second substrate, and the spacer layer comprises a plurality of spacers; the metal layer is formed by a magnetron sputtering process and a patterning process;
orthographic projections of any two of the spacer, the black matrix and the metal layer on the first substrate are at least partially overlapped with each other; a sum of thicknesses of the spacer, the metal layer and the black matrix in a direction perpendicular to the first substrate is same at any position corresponding to the spacer.

10. The method for manufacturing the display panel according to claim 9, wherein the thicknesses of the plurality of spacers are same as one another;
forming the black matrix with a controlled thickness at a position corresponding to the spacer, such that the sum of the thicknesses of the metal layer and the black matrix is same at any position corresponding to the spacer.

11. The method for manufacturing the display panel according to claim 10, wherein the display panel comprises a plurality of first regions and a plurality of second regions; the thickness of the metal layer in the first region is different from the thickness of the metal layer in the second region; wherein the first regions and the second regions are alternately arranged;
the formation of the black matrix comprises:
forming a black matrix film by a coating process; wherein a deposition amount of the black matrix material is controlled by adjusting an operating voltage of a coating apparatus, so that the thickness of the black matrix film corresponding to the first region is different from the thickness of the black matrix film corresponding to the second region;
exposing the black matrix film by using a mask, and developing to form the black matrix.

12. The method for manufacturing the display panel according to claim 9, wherein the metal layer is formed on the first substrate;
the black matrix and the spacer are formed on the second substrate.

13. The method for manufacturing the display panel according to claim 9, wherein the metal layer comprises a gate metal layer, the gate metal layer comprises a gate line;
orthographic projections of the spacer and the gate line on the first substrate are at least partially overlapped with each other.

14. The method for manufacturing the display panel according to claim 9, wherein the metal layer comprises a gate metal layer and a source-drain metal layer, the gate metal layer comprises a gate and the gate line, and the source-drain metal layer comprises a source, a drain and a data line;
a gate insulation layer and an active layer are further formed in the display panel, and the gate, the gate insulation layer, the active layer, the source and the drain form a TFT;
the orthographic projections of the spacer and the TFT on the first substrate are at least partially overlapped with each other.

15. The method for manufacturing the display panel according to claim 9, wherein the metal layer comprises a gate metal layer and a source-drain metal layer, the gate metal layer comprises a gate line, and the source-drain metal layer comprises an auxiliary pattern; the auxiliary pattern corresponds to the gate line;
the orthographic projections of the spacer and the auxiliary pattern on the first substrate are at least partially overlapped with each other.

16. The method for manufacturing the display panel according to claim 15, wherein an area of the orthographic projection of the auxiliary pattern is smaller than an area of the orthographic projection of the spacer on the first substrate, the spacer is against on the auxiliary pattern.
